(19) United States
(12) Patent Application Publication
(10) Pub. No.: US 2022/0246328 A1
(43) Pub. Date: Aug. 4, 2022

(54) Cables with Low Capacitance and Switches for Variable Capacitance

(71) Applicant: Xiaozheng Lu, Dallas, TX (US)

(72) Inventor: Xiaozheng Lu, Dallas, TX (US)

(21) Appl. No.: 17/577,232

(22) Filed: Jan. 17, 2022

Related U.S. Application Data
(60) Provisional application No. 63/138,682, filed on Jan. 18, 2021.
(60) Provisional application No. 63/253,725, filed on Oct. 8, 2021.

(51) Int. Cl. H01B 11/22; H05K 1/02

(52) U.S. Cl. CPC H01B 11/22; H01B 11/12; H05K 1/0216

(57) ABSTRACT

This invention is represented by embodiments of raw cables configured for low capacitance in a variety of cable types, namely copper, copper fiber hybrid and HDMI. Further, embodiment cable assemblies are provided with circuitry and/or switches for altering signals and varying capacitance to additionally avoid communication problems. Overall cable capacitance is dramatically reduced allowing for long cable lengths to be effectively employed.

### CLAIM OF PRIORITY

This application claims priority to U.S. Provisional Application Nos. 63/138,682, filed Jan. 18, 2021, and 63/253,725 filed Oct. 8, 2021.

### FIELD OF THE INVENTION

The invention relates to new technologies and designs in communication cables that solve the problems of capacitance-caused signal delays and communication failures resulting therefrom, by reducing the capacitance in the communication cables. The invention also relates to switches for varying the capacitance of the system solving the problems of capacitance-caused signal delays and communication failures resulting therefrom.

### BRIEF DESCRIPTION OF THE DRAWINGS

FIG. 1 schematically shows a prior art multi-device communication conflict management system used in I²C (Inter-Integrated Circuit) protocol.

FIG. 2 schematically shows how capacitance in a communication line causes signal delays.

FIG. 3 schematically shows a prior art HDMI connector pin-configurations and conductor groups.

FIG. 4 schematically shows a prior art AOC (Active Optical Cable) raw cable cross section diagram.

FIG. 5 schematically shows one embodiment of the current invention fiber-copper hybrid HDMI cable's raw cable cross section diagram.

FIG. 6 schematically shows one embodiment of the current invention fiber-copper hybrid HDMI cable's raw cable cross section diagram.

FIG. 7 schematically shows one embodiment of the current invention copper only HDMI cable's raw cable cross section diagram.

FIG. 8 schematically shows one embodiment of the current invention switches for variable capacitance circuit diagram.

FIG. 9 schematically shows one embodiment of the current invention HDMI cable plug with a switch for variable capacitance.

FIG. 10 schematically shows one embodiment HDMI Fiber-Copper Hybrid Cable Assembly Block Diagram.

### BACKGROUND

There are large demands for long communication cables in the real world, especially for consumer electronics, corporate media needs, and various industrial applications. The cables linking a computer below the desk to a monitor on the desktop only need to be 1 to 2 m (meter) (or 3 to 6 feet) long. The cables linking a media player in an equipment rack at the corner of a conference room to a large flat screen TV in the front of the conference room need to be 5 to 10 m (or 15 to 30 feet) long. The cables linking a main computer in the adjacent equipment room to an overhead projector in a conference room need to be 30 to 100 m (or 100 to 300 feet) long. The cables linking between devices between buildings need to be few km (kilometer) (or few miles) long. The undersea cables linking continents are in the thousands of km (or miles) long.

The electrical signal, as an electrical magnetic field, travels at light speed. However, the speed to transmit digital signals in highs (1s) and lows (0s) is much slower because the electrical current needs to charge the cable and device capacitance from low to high, then discharge it from high to low during transmission. The time to charge or discharge is determined by the formular τ=RC (RC Time Constant), where τ is the charge time, R is the system impedance, C is the system capacitance. The system maximum signal data rate is limited by this charge time delay. Most of the communication standards require the system impedance R to be a fixed number (like 75 ohm, 100 ohm, etc.) to reduce signal reflections, so the main method to reduce the time delay and improve the communication reliability is to reduce the system, mainly the cable's overall capacitance.

Most of the modern digital communication standards like DVI (Digital Visual Interface), HDMI (High-Definition Multimedia Interface), DP (DisplayPort), MHL (Mobile High-Definition Link), etc. have 3 groups of conductors in a signal cable. The 3 groups are as follows: Group A for one direction high speed data transmission for audio, video or Ethernet streaming; Group B for bi-direction low speed data for DDC (Display Data Channel) data (that often includes EDID (Extended Display Identification Data), HDCP (High-bandwidth Digital Content Protection)), CEC (Consumer Electronics Control) or other utility data; and Group C for ground, remote power, HPD (Hot Plug Detection) and like functions.

Most of the standards use I²C (Inter-Integrated Circuit) protocol for its simplicity.

The I²C protocol relies on a timing sensitive scheme to resolve multi-device communication conflicts known as “Arbitration” using transmitter comparing the data on serial data line (SDA) with data it intends to send.

Many of the audio video communication cables are quite long in lengths used commercially. Many of these long cables have higher I²C conductor to ground capacitance that causes the often-experienced I²C data delays. These delays often render the I²C “Arbitration” not possible to function, and causes multi-device communication conflicts to happen, and ends in the communication breakdown of the whole system.

The I²C specifications (Specs) for HDMI require the SDA (Serial Data) line to ground and SCL (Serial Clock) line to ground capacitances no more than 700 pF. The current prior art AOC (Active Optical Cable) cable's SDA to ground and SCL to ground capacitances are as high as 160 pF/m (pF per meter) or 48 pF/foot. This means even a short 5 m (16 feet) cable's total capacitance is already 800 pF, exceeding for example the I²C's specifications maximum allowed capacitance of 700 pF. A long 100 m (330 feet) cable's total capacitance is a huge 16,000 pF, exceeding the I²C's specifications maximum allowed 700 pF by many times. Systems linked with these cables will not have reliable I²C communications (or other communication protocols) and the communication often breaks down from exceeding capacitance limits. Installers and service engineers often need to troubleshoot and change devices in the system to make the system function for signal communication. This is not desirable and remains an ongoing problem in many industries.

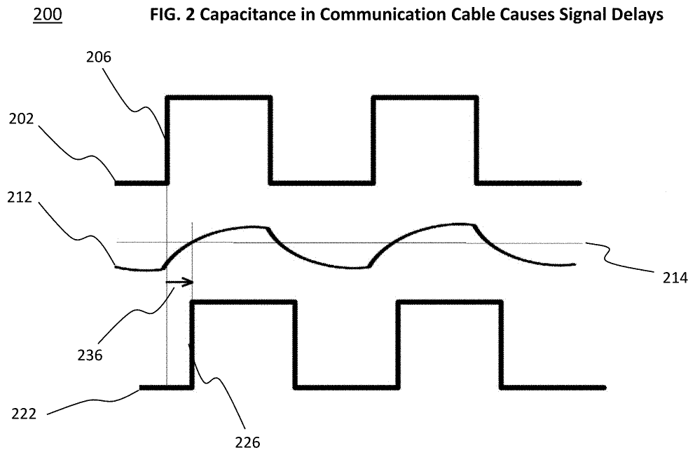

Many attempts by multiple inventors in the past two decades sought to solve these problems and have not been successful. The prior art collectively has been focused on what to do when the cable capacitance is high, and no prior art has been able to solve the problems' root cause, namely that the long cables' have high capacitance due to design limitations. For example, prior art patents U.S. Pat. Nos. 8,964,861 and 9,397,750 use I²C signal acceleration or conditioning, which is basically to restore the round edges of the square wave signal after the long cable to straight edges, but they cannot make the already delayed signal to happen before the current time to erase the time delay (see FIG. 2). The inventors do not solve the problem. Patent U.S. Pat. No. 8,984,324 uses a proprietary protocol to reduce the I²C clock frequency to compensate the timing delay caused by the long cable's high capacitance. For example, if the capacitance is 10 times over the I²C's capacitance limit, the protocol would lower the I²C data clock frequency by 10 times. This method does not work in the real world because it requires all devices in the system to have this non-standard protocol in their firmware; also, a much-reduced data clock frequency would make the data throughput too low for HDCP communication which must transmit new encryption keys every 2 seconds. Thus, the inventors have not solved the problem at hand and have created a new one for effective system commercialization.

### SUMMARY

Embodiments of this invention are communication cables that places the Group B conductors in the center of the raw cable cross section, far away from the raw cable's overall shield, and also away from the Group C conductors to reduce the conductor to ground capacitance. Other embodiments of this invention remove the ground conductors or shield from the raw cable to dramatically reduce the conductor to ground capacitance. By this cable construction design, the capacitance per meter length of the Group B conductors to ground is dramatically reduced to as low as 8 pF/m, and thus the total capacitance of long cables is dramatically reduced. This innovative non-obvious design recognizes the fundamental problem to be solved and does so by reducing capacitance between these key conductors to ground. Embodiment cables can be made as long as 100 m (330 feet) long or longer that are still in compliance of the I²C capacitance specs.

Although the Figures in the patent application show four embodiment examples of the HDMI cables, one skilled in the art would recognize that this invention can be configured and used in wide variety of cables including but not limited to DVI, HDMI, DP, MHL. Although the Figures in the patent application show embodiments of a fiber-copper hybrid cable and a copper only cable, this invention can be configured and used in wide variety of cables including but not limited to passive or active cables, twisted pair or coax cables, aluminum or steel cables, or any other cable.

Sometimes a communication cable can be too long to meet the I²C capacitance requirements; or if the cable itself meets the I²C capacitance requirements, but the overall system I²C capacitance can still exceed the I²C requirements when the I²C capacitance from the connected devices are added to a system. Added embodiments of the current invention provides a solution for this situation by including a dual in-line package (DIP) switch in the cable's plug body or on device panels. DIP switches are manual electric switches that is packaged with others in a group in a standard DIP. In embodiments this DIP switch controls a switch circuit that can add or not add capacitance to each of the I²C's SDA and SCL lines to ground respectively. This change of capacitance will alter the SDA and SCL line signal delays in small discrete amounts to allow system communication. If the I²C multi-device communication conflicts happen when the DIP switch in one position (system total capacitance in one value), then this communication conflicts won't happen when the DIP switch in other position (system total capacitance in another value). So, the end-user simply needs to flip the switch to fix the communication conflict when it happens. Although this application uses I²C as an example, embodiments of this current invention can be used for all communication protocols like RS232, RS485, TCP/IP, USB, Bluetooth, FTP, SSH, TELNET, SMTP, POP3, IMAP4, HTTP, HTTPS, SIP or many others. Cable embodiments of this current invention reduce the cable capacitance thus to reduce the communication delay in systems; or use switch embodiments to vary the system capacitance to avoid actual or possible communication conflicts. Any of the software protocol can benefit from this hardware improvement.

Although the figures and descriptions are showing the switches for variable capacitance solution to avoid the communication conflicts, this current invention also covers the variable resistance solution to avoid the communication conflicts. The time delay τ=RC. Changing either R (resistance) and/or C (capacitance) can change the delay timing τ and avoid the communication conflicts. Although the user interface in the figure and description here is DIP switch, it can also be touch panel, push button, computer or smartphone app, etc. Although the capacitance change execution circuit in the figure is electronic switches, it can also be mechanical switches, voltage controlled variable capacitors, resisters. These variable options are also covered under this patent application.

In embodiments a communication cable comprises one or more conductor for timing critical two-way communication; one or more ground component; one or more non-conductive component laid in between the one or more conductor and one or more ground component to make the distance between the conductor and ground component as far apart as possible to reduce the capacitance between the components; wherein the distance between the one or more conductor and the one or more ground component are separated by the one or more non-conductive component can be about 0.5 mm, about 1 mm, about 2 mm, about 5 mm, and from about 0.1 to about 20 mm. In other embodiments the communication cable is a DVI, HDMI, DP, MHL cable, or other commercially available cables. Different embodiments further comprise a two-way communication protocol for the one or more conductors in the communication cable embodiments above, wherein the two-way communication protocol is I²C, IP, RS232, RS485, USB, Bluetooth, FTP, SSH, TELNET, SMTP, POP3, IMAP4, HTTP, HTTPS, and SIP, or other protocols proprietary or as commercialized.

In certain embodiments the communication cables of paragraph [0021] further comprises a jacket, an overall braid shield; and an overall foil wrap over individual conductors. Other such, have the conductor or conductors for timing critical two-way communications laid in the center of the raw cable, with non-conductive component and other conductors laid in the space between the at least one conductor for timing critical two-way communications and the overall shield of the at least one ground component in the outmost position. In other embodiments of this invention, the cable's overall conductive shields, including the overall braid shield and overall foil wrap, are removed to achieve the maximum reductions for the capacitance between the communication conductors and ground.

In specific embodiments the one or more non-conductive component in the communication cable embodiments may be Nylon fillers, Teflon tape, cotton paper, PVC tube, and other non-grounded conductors and insulators.

In still other embodiments a switch either on the cable plug body or on a device panel comprises a User Interface; one or more resisters or capacitors; one or more communication conductors; and at least one Execution Circuit, wherein the User Interface controls the Execution Circuit; and wherein the Execution Circuit can connect or disconnect a resister or capacitor to each of the communication conductors. In such embodiments the communication cable's User Interface may be a DIP switch, a toggle switch, a push switch, a rotary switch, or a computer or a smartphone application command. In such further embodiments the communication cable's Execution Circuit can be electronic switches, mechanical switches, voltage controlled variable capacitors, or resisters. Also, in other such embodiments the communication cable signals of the cable carries may be I²C, IP, RS232, RS485, USB, analog horizontal sync pulse, and vertical sync pules and wherein interconnect standards of the communication cable or device is chosen from the group consisting of DVI, HDMI, DP, MHL, USB, VGA, and RGBHV.

The current invention provides multiple ways to reduce the fiber-copper hybrid or copper-only long cables' capacitance, and thus resolves the multi-device communication conflicts problem once and for all. The I²C conductor to ground capacitance is reduced surprisingly to as low as 8 pF/m or 2.4 pF/feet, or as much as 20 times from the current prior art. With embodiments of this invention, a very long 30 m (100 feet) cable's total capacitance is only 240 pF, well within the I²C specifications' maximum allowed 700 pF. Even a very long 100 m (330 feet) cable's total capacitance is only 800 pF, marginally very close to the specification's maximum allowed 700 pF, and in real life can provide virtually perfect communications. Thus, embodiments of the current invention vastly expand the cable length range that can have perfect or near perfect communications and solved many real-life application needs. In addition, the current invention uses the symmetrical components layout design in the raw cable's cross section, and adds space fillers to maintain the round shape of the overall raw cable bundle. These designs can take full advantage of the currently available production machines and keep the new raw cable production costs low. Embodiments of the current invention also provides alternative ways to make the system work even when the system total communication line capacitance is higher than the I²C specs allow by using switches to change the system capacitance.

### DETAILED DESCRIPTION

### Prior art I²C Arbitration

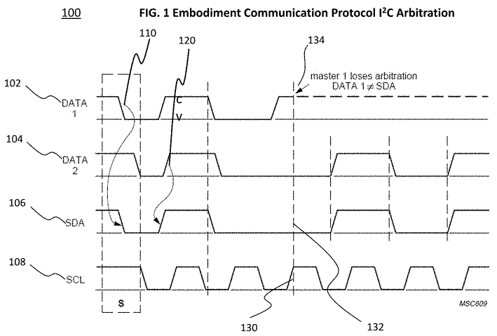

Referring to FIG. 1, shown schematically is a waveform view 100 of how the I²C arbitration protocol works. I²C connects to multiple devices; each device can be a master (sending data) or a slave (receiving data) (102, 104), but there can only be one master at any given time. When more than one device becomes the master at any given time, a communication conflict happens. In FIG. 1, 102 is the data of one device trying to send; 104 is the data of another device trying to send at the same time while 106 is I²C's SDA (serial data line, or bus) data waveform. Signal 108 is I²C's SCL (serial clock) line (or bus) clock waveform. When the two master's data are relatively similar during the timing 110 and 120, the SDA line follows both master's data. At timing 130, the master 1's data 102 is a logic “1”, the master 2's data 104 is a logic “0”. In this condition, the SDA line data follows the logic “0”, at the point of 132. At this time, master 1 discovers that the SDA line data did not follow its own data 134, and thus realizes that there's another master sending data, this master 1 losses Arbitration, and would change to a slave (receiving) for now. In this Arbitration protocol, timing is critical to data communication. Each device needs to be relatively in sync with the communication line delay insignificant comparing to the SCL clock period to make these conflict recognition and Arbitration to work allowing data communication in a system. Embodiments of the current invention's purpose is to make this critical I²C communication work reliability in long cables needed for real-life applications. See paragraph [0034] to [0040] for more details.

Prior Art: Why Signal Reshape does not Work

Referring to FIG. 2, shown schematically is a waveform view 200 of a square wave of an original signal 202, the “rounded” edge of a signal 212 after a communication line with capacitance, and a square wave of a signal 222 after signal reshaping (or accelerating or conditioning) circuit. The original signal 202's rising edge is at timing 206. Once the signal 212 becomes a “rounded” edge, the reshaping circuit is set to change the data from logic “0” to logic “1” after the signal voltage crossing the pre-determined threshold 214, and outputs signal 222 now with a rising edge at timing 226. The timing 226 is clearly always behind timing 206. The difference is the communication line delay 236. No matter how close the reshaped signal 222 is to the original signal 202 in wave form shapes, this time delay 236 always exists. Since the receiving device at the far end of the communication line that receives the signal 212 can't predict what would happen in future from its perspective, there's no way this receiving device can make the reshaped signal 222's rising edge to happen before its received timing 226. In other words, once the signal is delayed, it can't be “un-delayed” in any way. This is why the I²C “accelerating” or “conditioning” methods in prior art won't solve the problem with fiber-copper hybrid or copper only long cables with I²C communication conflicts. Embodiments of the current invention are designed to overcome these deficiencies and to make I²C communication work reliability in long cables needed for real-life applications. See paragraph [0034] to [0040] for more details.

### Prior Art: Communication Cable Conductor Groups

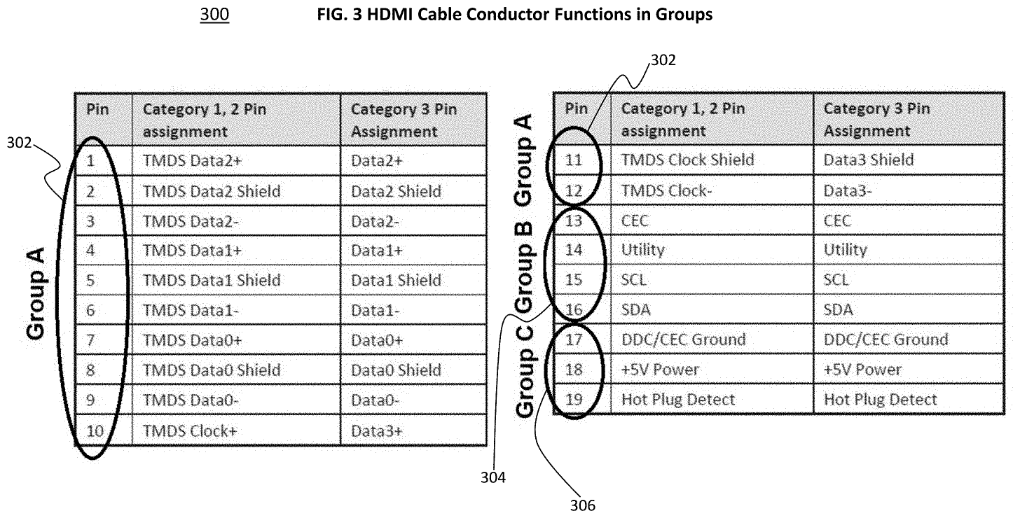

Referring to FIG. 3, 300 shown schematically is connector pin/conductor configuration diagram of an HDMI cable. Of the 19 pins/conductors, the first 12 conductors (pin 1 thru 12) form 4 TMDS (Transition-minimized differential signaling) or FRL (Fixed Rate Link) pairs. These conductors are sending high data rate one-way signals. These pins/conductors can be categorized as Group A 302 conductors. The next 4 conductors (pin 13 thru 16) are for relatively low speed two-way signals like the CEC, Utility, and the SCL and SDA lines of the I²C communications; this set of pins/conductors can be categorized as Group B 304 conductors. The last 3 conductors (pin 17 thru 19) are for ground or ground related functions like 5 V power, HPD (Hot Plug Detection); this final group of pins/conductors can be categorized as Group C 306 conductors. The impedance between any power line including the 5 V power and ground is virtually zero, so 5 V power line is ground related. The HPD is connected to 5 V power line, so it's also ground related. Embodiments of the current invention are multiple manufacturable solutions to make the Group B conductors to ground capacitance as small as possible to make I²C communication work reliability in long cables needed for real-life applications. See paragraph [0034] to [0040] for more details.

### Prior Art: Raw Cable Capacitance Basics

The formula of the capacitance per meter between two parallel flat conductors is:

$$\hat{C} = \frac{{ϵ}_{0} {ϵ}_{r} w}{d} ,$$

where the w is the area of the flat conductor, and the d is the distance between the two conductors. The formula of the capacitance per meter between two parallel round conductors is:

$$\hat{C} = \frac{π {ϵ}_{0} {ϵ}_{r}}{{cosh}^{- 1} ( D / a )} ,$$

where the D is the distance between the center of the two conductors, and a is the OD (overall diameter) of each conductor. In either case, the longer the distance d or D between the conductors, the lower the capacitance per meter between them. Also, the capacitance per meter is a fixed number for a given raw cable structure, and the total capacitance of a given cable is proportional to the length of the cable, thus longer the cable, the higher chance for I²C communication problems. In both cases, εₒ is the permittivity of the free space

$${ɛ}_{o} = \frac{1}{4 π \times 9 \times {10}^{9}} = 8.85 \times {10}^{- 12} F / m$$

The εᵣ is the relative permittivity of the medium. The εᵣ of air is about 1; Teflon 2.1; paper 2.3; Nylon 4 to 5. So, the preferred and most effective ways to reduce the cable capacitance is to make the conductors (to ground) further apart, and/or fill the gaps in between by non-conductive component with the smallest εᵣ. The non-conductive component can be any suitable wrap, tube, filler, grid, or simply air (gas, gasses, or space). The raw cable size is scalable depending on the cable applications. For mid length cables, the distance between the conductors to ground wires in a raw cable separated by non-conductive component can be a 0.5 to 3 mm. For the very long cables, this can be 5 to 20 mm. When needed, the space between conductors should be filled with non-conductive space fillers to maintain the cable integrity. The air (gas, gasses, or space) has the smallest εᵣ and should be first choice to use to reduce the capacitance. Teflon, paper and Nylon are also some good materials to use a space filler and represent additional embodiments.

### Prior Art AOC (Active Optical Cable) Raw Cable Cross Section

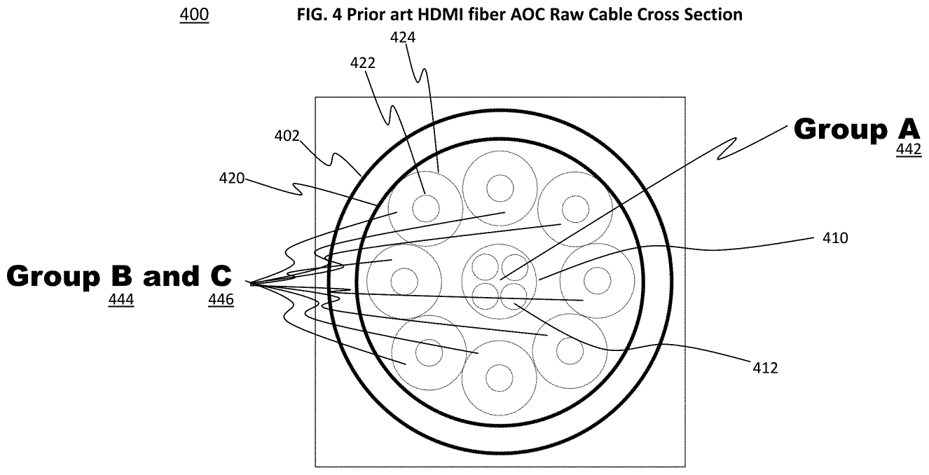

Referring to FIG. 4, shown schematically is a prior art AOC (Active Optical Cable) raw cable cross section diagram 400. The Group A 442 cables in this fiber cable are 4 fiber optics cables 412 wrapped together by a thin material 410. This thin material can be Teflon tape, cotton paper, or other materials. Group B 444 and Group C 446 conductors 422 are covered by a thin insulation material 424 and are not distinguished from each other and are randomly laid inside an overall shield layer 420. This shield layer 420 can be copper or aluminum braiding and/or aluminum foil wrap or other similar material known in the art. On the outside most is the overall jacket 402. This cable jacket 402 can be PVC jacket or other suitable non-conducting material known in the art. In this common design, the Group B 444 conductors 422 are touching the overall shield 420 which is grounded, thus the distance between 422 and 420 is very small. Based on the general discussions in section paragraph [0033], this very small distance results in very high capacitance between the Group B 444 conductors including the I²C's SCL and SDA conductors 422 and the shielding ground 420. In addition, since the Group C 446 conductors 422 are in-distinguishably laid with the Group B 444 conductors 422, most likely a Group B 444 conductor is touching a Group C 446 conductor from one or two sides. Group C 446 conductors are ground or ground related conductors. This very small distance between the Group B's I²C conductors to the Group C's ground related conductors also make the capacitance between them very high. The close distance between I²C conductors to the overall shield and to the ground related conductors is the root cause of the I²C communication problems in AOC and copper only long cables. Such prior art HDMI AOC cable assemblies made with raw cables shown in FIG. 4 cannot work reliably over about 5 meters (or 17 feet) because its I²C capacitance will exceed the max 700 pF allowed by the HDMI specs. This length limitation won't fit the common applications like connecting laptops on the conference tables to the big screen TV on the front wall of the conference room. Embodiments of the current invention are to overcome these deficiencies and to make I²C communication work reliability in long cables needed for real-life applications.

### Current Invention: Fiber Copper Hybrid Cable; Raw Cable Cross Section

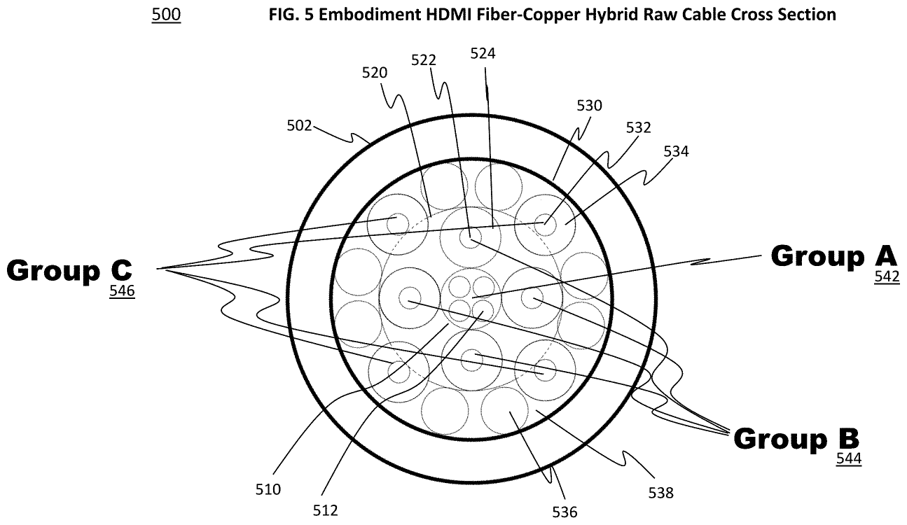

Referring to FIG. 5, shown schematically is a one example of the current invention raw cable cross section 500 comprising a Fiber-Copper Hybrid HDMI cable. In one embodiment 4 of the Group A 542 fiber cables 512 are laid in the center of the cable cross section, and are wrapped together by thin non-conductive layer 510. This layer 510 can be Teflon tape, cotton paper or thin PVC tube or like materials known in the art. In one embodiment, 4 of the Group B 544's conductors 522 and their insulators 524 are laid around the Group A 542 fiber strands 512 that are bundled by their own wrap 510, and are wrapped together by thin non-conductive layer material 520. This layer 520 can be Teflon tape, cotton paper, thin PVC tube or formed materials or like non-conductive material known in the art. The thickness of this layer 520 can be chosen to achieve the desired mechanical strength, for example, about 0.1 mm, about 0.5 mm, about 1 mm, about 2 mm, and from about 0.1 to about 20 mm in any reasonable increment of different sized cable (e.g., 0.05 mm; 0.1 mm; 0.2 mm; 0.5 mm and so on). In this embodiment, 4 of the Group C 546 conductors 532 and their insulators 534 are laid evenly around the Group B 544 bundle. Importantly, the space in between the Group C 546 conductors 532 are filled by space fillers 536 to maintain the overall round shape of the raw cable cross section, to prevent components inside the raw cable from moving around, and to make the manufacturing processes easier with existing machines. The air (space) has the smallest εᵣ and should be first choice to use to reduce the capacitance. Teflon, paper and Nylon or novel nonconducting flexible or firm materials are also preferred materials to use a space filler. All these components are wrapped together by overall shield 530. This overall shield can be aluminum braiding and/or aluminum foil wrap or other suitable material known in the art. Further, outside is the overall jacket 502. This jacket 502 can be PVC, TPE, FEP or other materials known to be suitable in the art. In this design, the timing critical Group B 544 conductors 522 are configured as far away from the overall shield 530 as possible, and thus the capacitance between these conductors to ground is as small as possible. This is the key novel and non-obvious essence of embodiments of this invention solving the I²C AOC and Hybrid long cable communication problem. Such FIG. 5 based current invention embodiment fiber-copper hybrid raw cables reduce the I²C capacitance per meter by about 5 times comparing to the prior art AOC raw cables shown in FIG. 4. This enables the current invention HDMI cable assemblies up to 25 m (or 83 feet) will still have the I²C capacitance within the max 700 pF HDMI specs and thus work reliably; such lengths can fit the needs for connecting laptops from the conference table to the TV on the front wall of a medium to large sized conference room. The distance between the Group B conductors to ground wires is scalable depending on the cable applications. For mid length cables, the distance between the conductors to ground wires in a raw cable can be about 0.1 to about 3 mm. For the very long cables, this can be about 3 mm to about 10 mm or even 20 mm. All the non-conductive components that fill the space between the Group B conductors 544 from the overall shield 530 and keep them separate, include thin layer 520, space filler 536 and empty space 538, are collectively called the “non-conductive component”. All the overall shield 530 and any conductors in Group C 546 that connected to ground inside the devices are collectively called “ground component”. All other variables like the materials or number of conductors, the functions of the conductors, the cable names, standards, protocols are just embodiment examples of where this invention can be used and are known in the art by skilled engineers and are covered by this invention.

### Current Invention: Fiber-Copper Hybrid Cable; Raw Cable Cross Section

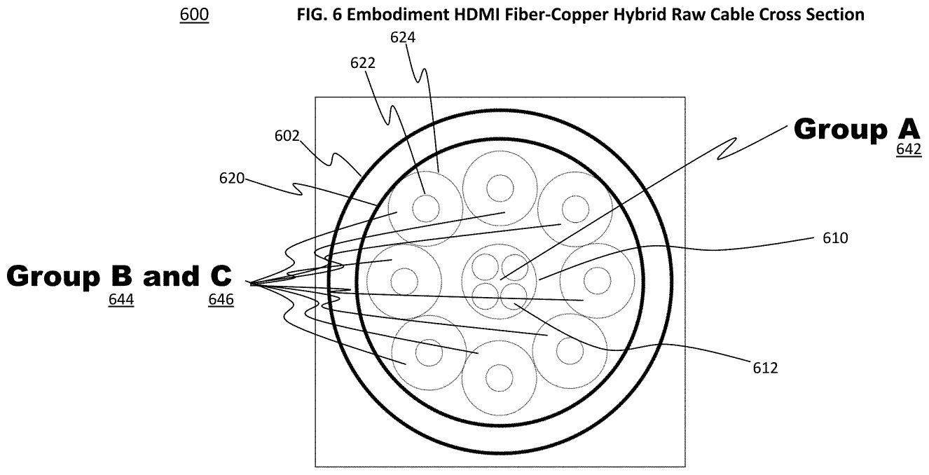

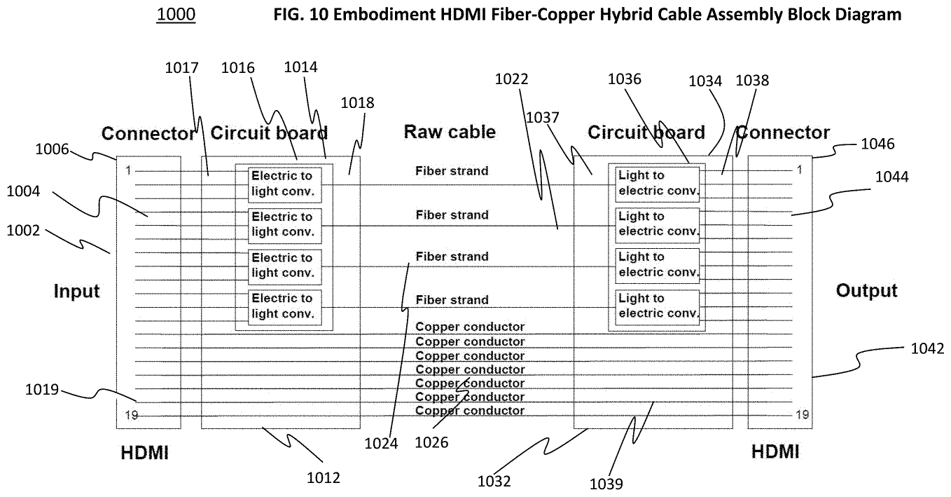

Referring to FIG. 6, shown schematically is a one embodiment of the current invention raw cable cross section 600 comprising a fiber-copper Hybrid HDMI cable. The Group A 642 cables in this fiber cable are 4 fiber optic cables 612 wrapped together by a thin material 610. This thin material can be Teflon tape, cotton paper or other non-conducting materials known in the art. Group B 644 and Group C 646 conductors 622 are covered by a thin insulation material 624 and are not distinguished from each other and randomly laid inside an overall non-conductive wrapping layer 620. This non-conductive layer 620 can be Teflon tape, cotton paper or other non-conducting materials known in the art. On the outside-most material of the cable is the overall jacket 602. This cable jacket 602 can be PVC jacket or other suitable non-conducting material known in the art. None, or as few as possible of the electrical conductors in Group B 644 or C 646 are connected to ground or terminals with low impedance to ground like the power supply either in the cable assembly itself 1000 (shown in FIG. 10) or through the connected electronics devices in a system; this ensures the minimum capacitance between the electrical conductors for low-speed data signal and system ground. Such FIG. 6 based embodiments of the current invention for fiber-copper hybrid raw cables reduce the I²C capacitance per meter by as much as 20 times comparing to the prior art AOC raw cables shown in FIG. 4. This enables the current invention HDMI cable assemblies to be up to 100 m (or 328 feet) that will still have the I²C capacitance within the max 700 pF HDMI specs and thus work reliably; such lengths can fit the needs for connecting laptops from the conference table to the TV on the front wall of a very large sized conference room or convention hall.

Referring to FIG. 10 descriptions are now at the cable assembly level with the raw cable described in paragraph [0036]. In the fiber-copper hybrid cable assembly embodiments, using the raw cables shown in FIG. 6, as shown is FIG. 10, there is a Circuit Board 1012 inside the male plug body of the input side with an IC chip 1014 that converts the high speed electronic TMDS signals into 4 channels of light signals and sent through the 4 strands of fiber cables 1024. There is another Circuit Board 1032 inside the male plug body of the output side with IC chip 1034 that converts the 4 channels of light signals from the 4 strands of fiber cables back to the high speed electronic TMDS signals. With this design, the biggest sources of EMI (Electromagnetic Interference) have been eliminated because the high speed TMDS signals are not sent in electronic form, but instead are sent via the 4 optical cables 612, shown in FIG. 6. Embodiments change the prior art conductive overall shield like the item 420 (in FIG. 4) into any suitable non-conductive wrapping 620, as shown in FIG. 6. Also, in some other embodiments, the signal and power ground on an input circuit in a male connector are connected to the source device via the male and female connectors, the signal and power ground on the output Circuit Board are connected to the sink device via the male and female connectors, and embodiments of the current invention does not connect any ground or power pins from the male connectors of the cable assembly to any of the conductors of the raw cable. These embodiments of the invention ensure that there is no ground shield, and as few ground conductors or power conductors (that has low impedance to ground) as possible along the full length of the raw cable near any of the DDC (Display Data Channel) conductors, thus the distance between these DDC conductors to any ground is far away, and thus the capacitance between DDC conductors to ground is very small. This is the key novel and non-obvious essence of embodiments of this invention solving the I²C long copper cable communication problem. Such FIG. 6 based current invention embodiment fiber-copper hybrid raw cables reduce the I²C capacitance per meter by about a surprising 10 times comparing to the prior art AOC raw cables shown in FIG. 4. This enables the current invention HDMI cable assemblies up to 50 m (or 167 feet) will still have the I²C capacitance within the max 700 pF HDMI specs and thus work reliably; such lengths can fit the needs for connecting laptops from the conference table to the TV on the front wall or a projector on the ceiling of a very large sized conference room. More detailed descriptions on this cable assembly level of invention are in the paragraph [0041].

### Current Invention: Copper Cable; Raw Cable Cross Section

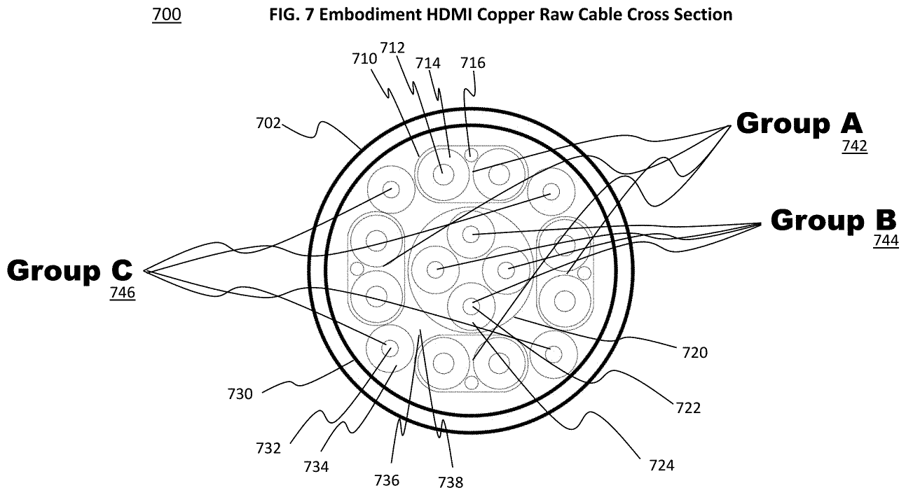

Referring to FIG. 7, shown schematically 700 is a one example of the current invention raw cable cross section of a copper HDMI cable. In this embodiment 4 of Group B 744's conductors 722 and their insulators 724 are laid in the center of the raw cable cross section, wrapped together by a thin layer 720. This layer 720 can be Teflon tape, cotton paper thin PVC tube or other suitable non-conducting material known in the art. The thickness of this layer 720 can be chosen to achieve the desired I²C capacitance per meter, for example, about 0.1 mm, about 0.5 mm, about 1 mm, about 5 mm, and from about 0.1 to about 20 mm. In this embodiment, 4 of the Group A 742's twisted pairs with their conductors 712, their insulators 714, the ground drain wire 716 wrapped by thin layer 710 for each pair, are laid evenly around the Group B 744's bundle. Here, 4 of the Group C 746's conductors 732 and their insulators 734 are also laid evenly around the Group B 744's bundle, and are interlaced between the Group A 742's 4 twisted pairs. All these components are wrapped together by overall shield 730. This overall shield can be aluminum braiding and/or aluminum foil wrap or other suitable material known in the art. Further outside is the overall jacket 702. This jacket 702 can be PVC, TPE, FEP or other materials or other suitable non-conducting material known in the art. In this design, the timing critical Group B 744 conductors 722 are as far away from the overall shield 730 as possible, thus the capacitance between these conductors to ground is as small as possible. This is the key novel and non-obvious essence of such embodiments of this invention solving the I²C long copper cable communication problem. The distance between the Group B conductors 744 to ground shields 730 or 710 is scalable depending on the cable applications. For mid length cables, the distance between the conductors to ground wires in a raw cable can be about 0.5 to about 3 mm. For the very long cables, this can be about 3 to about 20 mm. In other embodiments the distance between the conductors to ground wires in a raw cable can be about 0.5 mm to about 1 mm, or about 1 mm to about 2 mm, or about 2 mm to about 5 mm, or from about 0.1 to about 20 mm in about 0.1 mm increments, or larger dimensions. When needed, the space between conductors should be filled with non-conductive space fillers to maintain the cable integrity. The air (gas, gasses, or space) has the smallest εᵣ and should be first choice to use to reduce the capacitance. Teflon, paper and Nylon or novel nonconducting flexible or firm materials are also preferred materials to use a space filler. All the non-conductive components that fill the space between the Group B conductors 744 from the overall shield 730 and keep them separate, include thin layer 720, space filler 736 (if needed; not shown in this Figure) and empty space 738, are collectively called “non-conductive component”. All the overall shield 730, individual shield 710 and any conductors in Group C 746 that connected to ground inside the devices are collectively called the “ground component”. All other variables like the materials or number of conductors, the functions of the conductors, the cable names, standards, protocols are just examples of where this invention can be used known in the art by skilled engineers and are covered by embodiments of this invention. Such FIG. 7 based current invention embodiment copper raw cables reduce the I²C capacitance per meter by about 3 times comparing to the prior art AOC raw cables shown in FIG. 4. This enables embodiments of the current invention HDMI cable assemblies up to 15 m (or 50 feet) will still have the I²C capacitance within the max 700 pF HDMI specs and thus work reliably; such lengths can fit the needs for connecting laptops from the conference table to the TV on the front wall of a small to medium sized conference room.

### Current Invention: Switches for Variable Capacitance or Resistance Circuits

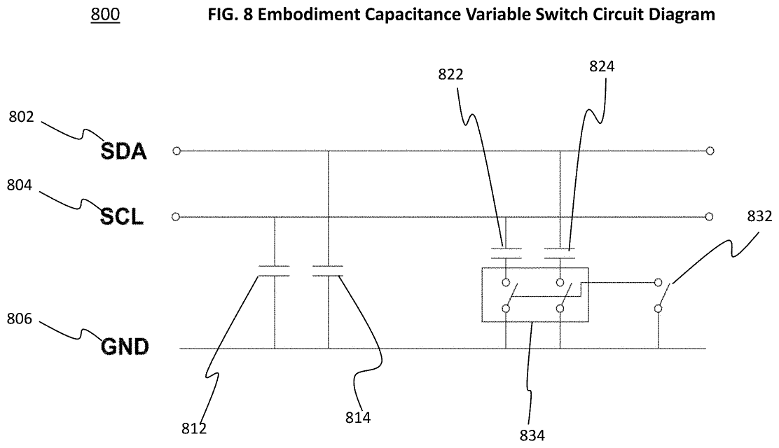

Referring to FIG. 8, shown 800 schematically is a one example of the current invention switchers for variable capacitance circuits. Embodiments of the first half of the current invention described in paragraphs [0035] to [0038] are to resolve the I²C communication problem from its root cause, which is to dramatically reduce the long cable's I²C capacitance. However, sometime in commercial applications very long cables are needed, the cable's I²C capacitance can still exceeding the I²C specs limit; or even the cable's I²C capacitance is within the I²C specs limit, the electronics devices at both ends have their own I²C capacitance too, the total system I²C capacitance can still exceed the overall specification limit. Embodiments of the second half of the current invention are intended to make the I²C communication still work even when the system I²C capacitance exceeding the I²C specs limit. When electronics devices detect an I²C communication error caused by a long delay, the devices will make further attempts to re-establish the communication a short time later, normally a few seconds later, for example 1, or 2 or 3 seconds later. If later communication succeeds, the users may not even know there was a communication problem. The communication problem will only become apparent to the user when the devices not only failed in the first attempt, and also failed repeatedly in the later attempts. For this to happen, all 3 conditions must all be met: 1) the I²C system capacitance exceeds the I²C specs limit; 2) more than one device attempt to send data at the same time; and 3) after previous failures, these more than one device attempt to send data again in the identical time interval. The item 1 and 3 are fixed parameters of a given system of devices and cables. The only item can be relatively easy to change is item 2: to change the system communication timing. The signal delay after a communication system is: τ=RC. So, changing the R (resistance) and/or C (capacitance) can alter the system's timing. The current invention is to make either embodiments of the cable capacitance or resistance variable controlled by a switch: in one embodiment a switch stage, a capacitor and/or resister is added to the current cable's communication line each, and in other switch stage, this capacitor and/or resister is not added. (See FIG. 8.) In this embodiment, 802 is the cable's I²C SDA line; 804 is cable's I²C SCL line; 806 is the cable's ground line (GND). In this embodiment 812 is the cable's native SDA line to ground capacitance. Here, 814 is the cable's native SCL line to ground capacitance. 832 is a User Interface switch. In different embodiments this switch can be a DIP switch, toggle switch, push switch, rotary switch, computer, or smartphone app command among other switches known by skilled engineers in the art. When the switch is in one stage, the Execution Circuit 834 will connect the capacitor 822 to the SCL line, and 824 to the SDA line respectively. When the switch is in another stage, the electronic switch circuit will disconnect them from those 2 lines respectively. The Execution Circuit can be electronic switches, mechanical switches (toggle switch, and a push switch, a rotary switch), voltage controlled variable capacitors, or resisters, as well as a computer or a smartphone application command. If the user experiences a system failure due to the I²C communication conflicts caused by high I²C capacitance, the user just needs to flip the switch from one stage to the other, then the system I²C communication timing will be altered slightly but effectively to prevent communication problems. This changes one of the 3 required conditions for sustained system failures described in this section earlier, and should make the system working again for effective I²C controlled data communication in a system. Embodiments of this invention are to alter the R and/or C of a communication system to make a failed communication work effectively. Different User Interfaces, Execution Circuits, the value of the added resisters or capacitors, the communication protocols, the cable types among other suitable components should be just examples of this invention known in the art by skilled engineers and are and are covered under this invention. Embodiments of this invention can also be used in the H (Horizontal) or V (Vertical) sync pulses circuit of an analog signal format like VGA or RGBHV or adapted to other signal formats.

### Current Invention: Switches for Variable Capacitance or Resistance Circuits User Interface

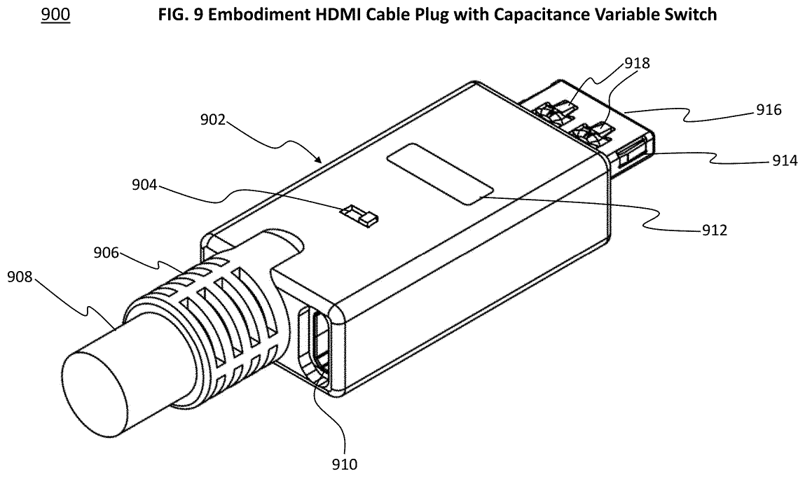

Referring to FIG. 8 and FIG. 9, shown 900 schematically is a one example embodiment of the current invention HDMI cable plug 902 with switch for variable capacitance circuits User Interface. The HDMI cable plug body 902 is connected to the raw cable 908 via a strain relief 906. On the plug body 902, a one bank DIP switch 904, which is also shown in FIG. 8 as item 832, has two possible switch positions. In one switch position, it sets the execution switch 834 as shown in FIG. 8, to Close position and connect the two capacitors 822 and 824 in FIG. 8 to their cable conductors respectively. In other switch position, it sets the Execution Circuit 834 in FIG. 8 to Open position and disconnect the two capacitors 822 and 824 in FIG. 8 from their cable conductors respectively. When the user experiences a I²C communication problem in the system in real use, the user just needs to flip the switch 904 from its current position to the other position. This will alter the I²C communication timing to avoid the communication collisions and make the system work again. This is only one embodiment of the user interface. Different user interfaces, execution circuits, the value of the added resisters or capacitors, the communication protocols, the cable types among other suitable components should be just examples of this invention known in the art by skilled engineers and are and are covered under this invention. Such HDMI cable plug 902 embodiments may also be configured with locking connectors 918, 914 on the male probe 916. Additionally, embodiments may have a visual indicator (LED or other) 912 to show when the signal is good. Other embodiments may have a connector 910 for receiving power from an external source (USB or other).

### Current Invention: Fiber-Copper Hybrid Cable Assembly Block Diagram

Referring to FIG. 10 shown is an embodiment of an HDMI Fiber-Copper Hybrid Cable Assembly Block Diagram. This cable assembly 1000 includes an input Connector 1002 with a Circuit Board 1012 in its plug body; an output Connector 1042 and a Circuit Board 1032 in its plug body; and a section of Raw Cable 1022 connecting the Input Connector 1002 and its Circuit Board 1012 with the Output Connector 1042 and its Circuit Board 1032. The input Connector 1002 consists of 19 pins 1004 with the pin numbering starting at pin number 1 1006. The 12 pins (pin 1 thru 12) that carry the high-speed electric signals are fed into IC 1014 for conversions. The input Circuit Board 1012 consists an IC chip 1014. The IC chip 1014 consists 4 Electric to Light converter circuit 1016. Each converter circuit 1016 takes in the electric signals from 3 input pins 1017 (input+, input− and ground), and converts it into light and outputs it from the light emission interface 1018. The 4 light outputs are transmitted to the other end of the cable assembly by 4 Fiber optic fiber strands 1024. The other low speed electric signals from input Connector 1002's pin 13 thru 16 are connected to the other end of the cable assembly directly by Copper conductors 1026. In the other end of the cable assembly, there's a Circuit Board 1032. The Circuit Board 1032 that consists an IC chip 1034. The IC chip 1034 consists 4 Light to Electric converter circuit 1036. Each converter circuit 1036 takes in light from 1 fiber optics strand 1037, and converts it into electric signals and outputs them thru 3 output pins 1038 (output+, output− and ground) to the output Connector 1042. With this design, the biggest sources of EMI (Electromagnetic Interference) have been eliminated because the high speed TMDS signals are not sent in electronic form, but instead are sent via the 4 optics cables 1024. The following additional embodiments can be implemented by one of them or both when the system has other means to connect the ground between devices than thru this HDMI cable (not shown in the FIG. 10). The 5 V line 1019 (pin 18) from the input connector 1002 is connected to the Hot Plug Detection pin 19 on the circuit board in the input side circuit board 1012 to provide the cable plugged in feedback to the source device. They are not connected to any of the raw cable conductors 1026. The 5 V line 1039 (pin 18) and the Hot Plug detection pin 19 to the output connector 1042 are not connected to any of the raw cable conductors 1026. Note that in preferred embodiments none or a minimum number of the ground pins (pin 2, 5, 8, 11, 17) and the pins that have low impedance to ground (pin 18, 19) on the input Connector 1002 are connected to the pins with the same pin numbers on the output Connector 1042 with its 19 pins 1044 with pin numbering starting at pin 1 1046 by any conductors of the Raw Cable 1026. Preferred embodiments utilize this key element, namely removing or reducing the ground pin connections for pins and connections to low impedance to ground of this version of the HDMI Fiber-Copper Hybrid Cable Assembly. One skilled in the art would know to apply this to other connector or cable formats, namely DP, DVI, MHL and any newly developed formats, and these are covered by embodiments of this invention. In certain embodiments the connector input end circuitry is for transmitting low speed electronic data signals including the CEC, Utility, SCL, and SDA, or other low speed data signal format.

What is claimed is:

1: A communication raw cable comprising at least one conductor for timing critical two-way communication comprising:
at least one ground component;
at least one non-conductive component laid in between the at least one conductor and the at least one ground component to make the distance between the at least one conductor and the at least one ground component as far apart as possible to reduce the capacitance between the conductor and ground components.

2: The communication raw cable of claim 1, wherein the distance between the conductor and the ground components separated by the at least one non-conductive component can be selected from the group consisting of about 0.5 mm to about 1 mm, or about 1 mm to about 2 mm, or about 2 mm to about 5 mm, or from about 0.1 to about 20 mm in about 0.1 mm increments, or larger dimensions.

3: The communication raw cable of claim 1, wherein the cable is chosen from the group consisting of DVI, HDMI, DP, MHL, or other commercially available cables.

4: A two-way communication protocol for the at least one conductor in the communication raw cable of claim 2, wherein the two-way communication protocol is selected from the group consisting of I2C, RS232, RS485, TCP/IP, USB, Bluetooth, FTP, SSH, TELNET, SMTP, POP3, IMAP4, HTTP, HTTPS, SIP, or other commercially available protocols.

5: The at least one ground component in the communication raw cable of claim 1, wherein the cable further comprises an overall braided shield; and an overall foil wrap over individual conductors.

6: The at least non-conductive component in the communication raw cable of claim 1, wherein the non-conductive component is selected from the group consisting of space (air), Nylon fillers, Teflon tape, cotton paper, PVC tube, and other non-grounded conductors and insulators.

7: The communication raw cable of claim 1, wherein the at least one conductor for timing critical two-way communications is laid in the center of the raw cable cross section, with non-conductive components and other conductors laid in the space between the at least one conductor for timing critical two-way communications and the overall shield of the at least one ground component in the outmost position.

8: The cable of claim 1, further comprising a cable assembly with an input and output connector.

9: A switch on a communication cable assembly or device to change system capacitance or resistance; the Switch comprising:
at least one User Interface;
at least one capacitor or resister;
at least one communication conductor; and at least one Execution Circuit,
wherein the User Interface controls the Execution Circuit; and wherein the Execution Circuit can connect or disconnect the at least one capacitor or resister to the at least one of the communication conductors.

10: The Switch of claim 9 wherein the at least one User Interface is selected from the group consisting of a DIP switch, a toggle switch, and a push switch, a rotary switch, a computer or a smartphone application command.

11: The Switch of claim 9, wherein the Execution Circuit can be selected from the group consisting of electronic switches, mechanical switches, voltage controlled variable capacitors, and resisters.

12: The Switch of claim 9, wherein the signals the cable carries are selected from a group consisting of I2C, IP, RS232, RS485, USB, analog horizontal sync pulse, and vertical syn pules or other commercially available signal formats and wherein interconnect standards of the communication cable or device of claim 7 is chosen from the group consisting of DVI, HDMI, DP, MHL, USB, VGA, and RGBHV or other commercially available cable standards.

13: A communication raw cable comprising at least one electrical conductor and at least one optical fiber strand;
a non-conductive wrapping sheet around the at least one optical fiber strands forming an optical subassembly;
a non-conductive wrapping sheet around all of the electrical conductors and optical strands;
a non-conductive overall jacket extruded outside the non-conductive wrapping sheet around all the electrical conductors and optical strands,
wherein there is no conductive overall shield surrounding the electrical conductors and optical strands.

14: The communication cable assembly comprising the raw cable of claim 13,
the cable assembly further comprising a first connector with a circuit board on the input end; and
a second connector with a circuit board on the output end;
a raw cable in between these two connectors, each with a circuit board in each end;
the circuit board on the input end comprising circuits to convert the at least one high speed electronic data signals into the at least one light signal and to transmit them through the at least one fiber strands of the raw cable; the circuit board on the input end further comprising circuits to transmit the at least one low speed electronic data signals through the at least one electrical conductor;
the circuit board on the output end comprising circuits to convert the at least one light signal received from the at least one fiber strands to an at least one high speed electronic data signal;
the circuit board on the output end further comprising circuits to receive the at least one low speed electronics data signals from the at least one electrical conductor.

15: The communication cable assembly of claim 14, wherein the ground pins and pins with low impedance to the ground of the input connector are not connected by the raw cable electrical conductors to the associated ground pins and the pins with low impedance to the ground of the output connector.

16: The materials of the non-conductive wrapping sheet and the non-conductive overall jacket in claim 13 are chosen from the group consisting of Teflon tape, cotton paper, PVC tube and other non-conductive materials.

17: The communication cable assembly of claim 14, wherein the communication cable type is chosen from the group consisting of DVI, HDMI, DP, MHL, USB, VGA, and RGBHV or other commercially available cable standards.

18: The communication cable assembly of claim 14, wherein the cable type is HDMI, and wherein the input end circuitry is for converting 4 TMDS high speed electronic signals into 4 light signals, for transmission through the 4 fiber strands; and wherein the input end circuitry is for transmitting low speed electronic data signals including the CEC, Utility, SCL, SDA through electrical the conductors;
and wherein the ground pins 2, 5, 8, 11 between the input connector and output connector are not connected to the raw cable conductors.
